(19) United States
(12) Patent Application Publication
(10) Pub. No.: US 2024/0322528 A1
(43) Pub. Date: Sep. 26, 2024

(54) HIGH-POWER COHERENT SEMICONDUCTOR OPTICAL AMPLIFIER ARRAY

(71) Applicant: University of Central Florida Research Foundation, Inc., Orlando, FL (US)

(72) Inventor: Guifang Li, Orlando, FL (US)

(21) Appl. No.: 18/615,775

(22) Filed: Mar. 25, 2024

Related U.S. Application Data
(60) Provisional application No. 63/454,400, filed on Mar. 24, 2023.

(51) Int. Cl. H01S 5/40; H01S 5/04; H01S 5/068; H01S 5/0683

(52) U.S. Cl. CPC H01S 5/4025; H01S 5/041; H01S 5/06821; H01S 5/0683; H01S 5/4012

(57) ABSTRACT

A light source may include an array of grating-coupled semiconductor optical amplifiers (GC-SOAs) arranged along a surface of a substrate, where the array of GC-SOAs receive seed light from a common seed source, and where the array of GC-SOAs provide an array of SOA output beams associated with amplification of the seed light at a non-zero angle from the surface of the substrate. A light source may further include one or more phase shifters configured to provide that the SOA output beams are phase-locked.

### CROSS-REFERENCE TO RELATED APPLICATION

The present application claims the benefit under 35 U.S.C. § 119(e) of U.S. Provisional Application Ser. No. 63/454,400, filed Mar. 24, 2023, entitled HIGH-POWER COHERENT SEMICONDUCTOR OPTICAL AMPLIFIER ARRAY, naming Guifang Li as inventor, which is incorporated herein by reference in the entirety.

### TECHNICAL FIELD

The present disclosure relates generally to coherent combination of laser light and, more particularly, to chip-scale integrated coherent combination of grating-coupled silicon optical amplifier arrays into a single output beam.

### BACKGROUND

Directed energy has the ability to weaponize electricity, turning batteries and energy grids into powerful and economical weapons. At the forefront of the Directed Energy movement are Laser Weapon Systems (LWSs) based on high-energy lasers (HELs). One significant setback to current LWSs is their lack of scalability. For instance, LWSs based on fiber lasers/amplifiers, a leading HEL technology, are large, heavy and complex, impacting mission readiness. Chip-scale integrated coherent beam combining (CBC) technology can be a potential alternative to fiber lasers/amplifiers. However, existing chip-scale CBC techniques suffer from low power, poor scalability, and/or high optical loss. There is therefore a need to develop systems and methods that address the above deficiencies.

### SUMMARY

In embodiments, the techniques described herein relate to a light source including an array of grating-coupled semiconductor optical amplifiers (GC-SOAs) arranged along a surface of a substrate, where the array of GC-SOAs receive seed light from a common seed source, where the array of GC-SOAs provide an array of SOA output beams associated with amplification of the seed light at a non-zero angle from the surface of the substrate.

In embodiments, the techniques described herein relate to a light source, further including one or more phase shifters configured to provide that the SOA output beams are phase-locked.

In embodiments, the techniques described herein relate to a light source, further including a plurality of phase masks configured to coherently combine the array of SOA output beams into a single output beam.

In embodiments, the techniques described herein relate to a light source, where the plurality of phase masks are associated with a multi-plane light conversion (MPLC) device.

In embodiments, the techniques described herein relate to a light source, where the single output beam has a Gaussian profile.

In embodiments, the techniques described herein relate to a light source, where the plurality of phase masks are reflective phase masks, where the light source further includes a mirror, where light associated with the array of SOA output beams is successively reflected between the mirror and the plurality of phase masks to coherently combine the array of SOA output beams into the single output beam.

In embodiments, the techniques described herein relate to a light source, where the plurality of phase masks are transmissive phase masks, where light associated with the array of SOA output beams is successively transmitted through the plurality of phase masks to coherently combine the array of SOA output beams into the single output beam.

In embodiments, the techniques described herein relate to a light source, where the array of GC-SOAs is arranged as two or more rows of GC-SOAs, where the light source further includes one or more couplers arranged to split the seed light into the two or more rows.

In embodiments, the techniques described herein relate to a light source, where light not outcoupled as one of the SOA output beams from at least one GC-SOA in a particular row of the two or more rows seeds at least one subsequent GC-SOA in the array of GC-SOAs in the row.

In embodiments, the techniques described herein relate to a light source including an array of GC-SOAs arranged along a surface of a substrate, where the array of GC-SOAs receive seed light from a common seed source, where the array of GC-SOAs provide an array of SOA output beams associated with amplification of the seed light at a non-zero angle from the surface of the substrate; one or more phase shifters configured to control phases of the SOA output beams; a control sub-system including one or more detectors configured to generate detection signals indicative of phases of the SOA output beams; and a controller communicatively coupled to the one or more phase shifters and the one or more detectors, where the controller includes one or more processors configured to execute program instructions stored on a memory device, where the program instructions are configured to cause the one or more processors to; receive the detection signals from the one or more detectors; and generate control signals for the one or more phase shifters based on the detection signals to phase lock the SOA output beams.

In embodiments, the techniques described herein relate to a light source, where the control sub-system further includes an interferometer configured to interfere a portion of the seed light with at least one of a portion of the SOA output beams or tapped light from the GC-SOAs onto one of the one or more detectors.

In embodiments, the techniques described herein relate to a light source, where the one or more detectors include a multi-pixel detector.

In embodiments, the techniques described herein relate to a light source, further including a plurality of phase masks configured to coherently combine the array of SOA output beams into a single output beam.

In embodiments, the techniques described herein relate to a light source, where the plurality of phase masks are associated with a MPLC device.

In embodiments, the techniques described herein relate to a light source, where the single output beam has a Gaussian profile.

In embodiments, the techniques described herein relate to a light source, where the plurality of phase masks are reflective phase masks, where the light source further includes a mirror, where light associated with the array of output beams is successively reflected between the mirror and the plurality of phase masks to coherently combine the array of output beams into the single output beam.

In embodiments, the techniques described herein relate to a light source, where the plurality of phase masks are transmissive phase masks, where light associated with the array of output beams is successively transmitted through the plurality of phase masks to coherently combine the array of output beams into the single output beam.

In embodiments, the techniques described herein relate to a light source, where the array of GC-SOAs is arranged as two or more rows of GC-SOAs, where the light source further includes one or more couplers arranged to split the seed light into the two or more rows.

In embodiments, the techniques described herein relate to a light source, where light not outcoupled as one of the SOA output beams from at least one GC-SOA in a particular row of the two or more rows seeds at least one subsequent GC-SOA in the array of GC-SOAs in the row.

In embodiments, the techniques described herein relate to a method including directing seed light to an array of GC-SOAs arranged along a surface of a substrate, where the array of GC-SOAs provide an array of SOA output beams associated with amplification of the seed light at a non-zero angle from the surface of the substrate; and coherently combining the array of SOA output beams into a single output beam.

In embodiments, the techniques described herein relate to a method, where coherently combining the array of SOA output beams into a single output beam includes coherently combining the array of SOA output beams into a single output beam with a plurality of phase masks.

In embodiments, the techniques described herein relate to a method, where the plurality of phase masks are associated with a MPLC device.

In embodiments, the techniques described herein relate to a method, further including adjusting phases of the seed light prior to at least some of the GC-SOAs with one or more phase shifters.

In embodiments, the techniques described herein relate to a method, further including generating detection signals indicative of phases of the SOA output beams; and generating control signals for one or more phase shifters to phase lock the phases of the SOA output beams.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1 is a block diagram of a light source, in accordance with one or more embodiments of the present disclosure.

FIG. 2A is a perspective view of an array of grating-coupled semiconductor optical amplifiers (GC-SOAs) on a common substrate, in accordance with one or more embodiments of the present disclosure.

FIG. 2B is a magnified view of a portion of the light source in FIG. 2A depicting an SOA and a phase shifter, in accordance with one or more embodiments of the present disclosure.

FIG. 2C is a cross-section schematic of a GC-SOA, in accordance with one or more embodiments of the present disclosure.

FIG. 3 is a conceptual top view of a GC-SOA array, in accordance with one or more embodiments of the present disclosure.

FIG. 4 is a schematic illustration of a non-limiting example of a light source with reflective phase masks 110 for coherent beam combining, in accordance with one or more embodiments of the present disclosure.

FIG. 5A is a plot of intensity of an array of 16 Gaussian beams, in accordance with one or more embodiments of the present disclosure.

FIG. 5B is a far-field intensity plot of the beams in FIG. 5A in the case that the beams are incoherent with respect to each other, in accordance with one or more embodiments of the present disclosure.

FIG. 5C is a far-field intensity plot of the beams in FIG. 5A in the case that the beams are coherent with respect to each other, in accordance with one or more embodiments of the present disclosure.

FIG. 5D is a far-field intensity plot of the beams in FIG. 5B upon coherent combination with phase masks operating as an multi-plane light conversion (MPLC) device, in accordance with one or more embodiments of the present disclosure.

FIG. 6 is a plot of normalized cumulative power as a function of beam radius for the intensity plots of FIGS. 5B-5D, in accordance with one or more embodiments of the present disclosure.

FIG. 7A is a plot of seven phase mask patterns suitable for combining an array of 64 SOA output beams, in accordance with one or more embodiments of the present disclosure.

FIG. 7B is a plot of intensity distributions associated with the conversion of the 64 SOA output beams to a single Gaussian output beam, in accordance with one or more embodiments of the present disclosure.

FIG. 8 is a flow diagram illustrating steps performed in a method for amplifying light, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods for generating laser output using a master oscillator power amplifier (MOPA) configuration with an array of semiconductor optical amplifiers (SOAs) on a common substrate pumped by seed light from a common source, where output beams (referred to herein as SOA output beams) from the array of SOAs is coherently combined with a series of phase plates. For example, the SOAs may be formed as grating-coupled (GC) SOAs that provide output beams at a non-zero angle with respect to a surface of the substrate. Put another way, the GC-SOAs may emit light out in free space out of a plane associated with the substrate. Further, the series of phase plates may form a multi-plane light conversion (MPLC) device. As an illustration, the phase plates may be reflective phase plates. In this configuration, the output beams may be successively reflected between a mirror and the phase plates to provide coherent combination of the SOA output beams into a single output beam. As another illustration, the phase plates may be transmissive phase plates (e.g., between two mirrors). In this configuration, the output beams may be successively transmitted through the phase plates to provide coherent combination of the SOA output beams into a single output beam. This single output beam may have any profile including, but not limited to, a Gaussian profile.

It is contemplated herein that the systems and methods disclosed herein may be described as a chip-scale integrated coherent beam combining (CBC) technique and may have numerous advantages over alternative techniques. For example, CBC using vertical-cavity surface-emitting laser (VCSEL) diodes may produce ˜500 mW, passive CBC of VCSELs in a common or coupled cavity geometry can only scale to ˜10 emitters. In particular, demonstrations using 2D VCSEL arrays have been limited to low power with poor prospects for scalability. As another example, CBC using edge-emitters in a master oscillator-power amplifier configuration may maintain reasonable CBC efficiency and output power with element counts greater than 200, but the semiconductor gain materials suffer from high optical loss and are poorly suited for direct photonic integration.

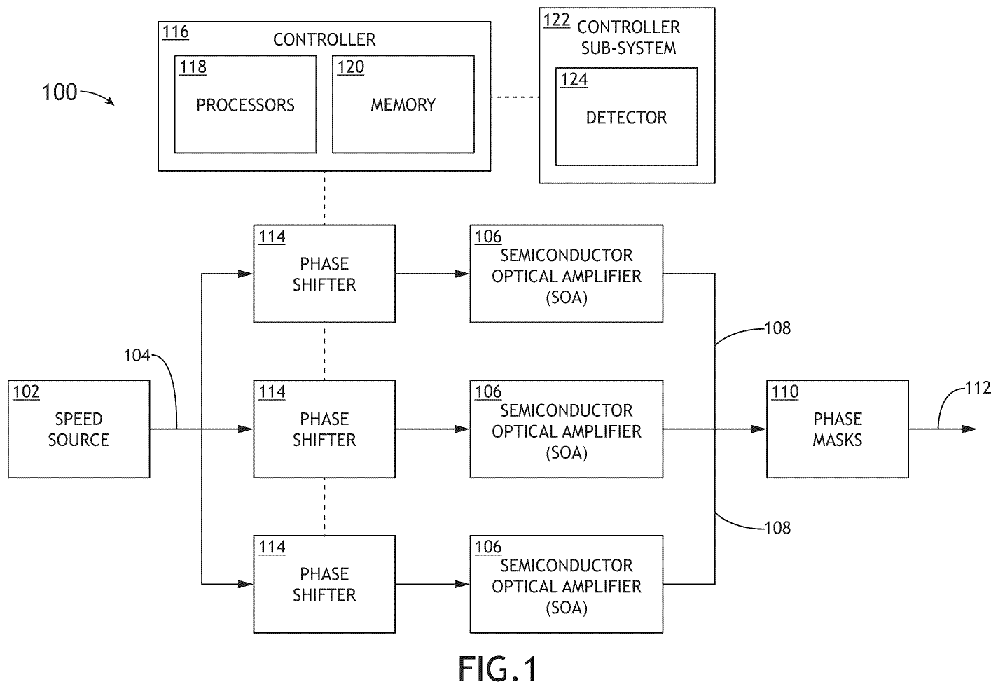

Referring now to FIGS. 1-7B, systems and methods for CBC using a SOA array is described in greater detail, in accordance with one or more embodiments of the present disclosure.

FIG. 1 is a block diagram of a light source 100, in accordance with one or more embodiments of the present disclosure.

In some embodiments, the light source 100 includes a seed source 102 configured to generate seed light 104, multiple GC-SOAs 106 (e.g., an array of GC-SOAs 106) to receive and amplify the seed light 104 to generate SOA output beams 108, and a series of phase masks 110 to coherently combine the SOA output beams 108 into a single output beam 112. In some embodiments, the light source 100 further includes one or more phase shifters 114 (e.g., phase modulators) to adjust the phase of the seed light 104 such that the SOA output beams 108 from the GC-SOAs 106 are in phase with each other (e.g. phase-locked). In this way, the light source 100 provide a phase-locked array of coherent SOA output beams 108 using a master oscillator-power amplifier (MOPA) array configuration.

The seed source 102 may include any type of light source suitable for providing seed light 104 to be amplified by the SOA output beams 108. In some embodiments, the seed source 102 is a laser source. In this way, there is flexibility in choosing the temporal dynamics of the input, and thus the output.

The seed source 102 may provide seed light 104 having any temporal or spectral characteristics suitable for amplification by the GC-SOAs 106. For example, the seed source 102 provides continuous-wave (CW) seed light 104. As another example, the seed source 102 provides pulsed seed light 104. In this configuration, the seed light 104 may have any repetition rate, pulse duration, and/or duty cycle suitable for amplification by the GC-SOAs 106.

The seed source 102 may provide seed light 104 having any wavelength or spectrum suitable for amplification by the GC-SOAs 106. For example, the seed light 104 may have wavelengths in the range of 900-1700 nm. As another example, the seed light 104 may have wavelengths in the range of 1250-1350 nm. As another example, the seed light 104 may have wavelengths in the range of 1450-1600 nm. In a general sense, the seed light 104 may have any wavelength or range of wavelengths supported by a GC-SOA 106 formed from any materials suitable for light amplification.

The SOAs 106 may further receive the seed light 104 from the seed source 102 using any suitable technique. In some embodiments, the seed source 102 is coupled to the SOAs 106 via waveguides (e.g., SiN waveguides, or the like).

The SOAs 106 may include any type of SOA known in the art. In some embodiments, the SOAs 106 include grating-coupled (GC) SOAs 106 that may provide an SOA output beam 108 at an angle with respect to the propagation direction of the seed light 104. Such a configuration may allow coupling of the seed light 104 into or through a substrate. For example, GC-SOAs 106 may provide an array of SOA output beams 108 emanating from a plane or surface including the GC-SOAs 106 (e.g., into free space).

The GC-SOAs 106 may be arranged in any suitable arrangement to provide an array of SOA output beams 108 for coherent combination with the phase masks 110. In some embodiments, the GC-SOAs 106 are located on a common substrate. For example, the GC-SOAs 106 may be integrated into a silicon photonic (SiPh) platform. The GC-SOAs 106 may be integrated onto the SiPh platform using any suitable technique such as, but not limited to, wafer bonding or transfer printing.

The seed source 102 may be provided in any form factor. In some embodiments, the seed source 102 is provided as a stand-alone component, which may provide the seed light 104 as a free-space beam or within an optical fiber. In this configuration, the seed light 104 may be coupled from the seed source 102 to the array of GC-SOAs 106 (e.g., into a waveguide on a common substrate as the GC-SOAs 106). In some embodiments, the seed source 102 is integrated into a common substrate as the GC-SOAs 106 (e.g., as part of a SiPh platform, or any other suitable integrated platform). In this configuration, the seed light 104 may be provided in one or more waveguides on the common substrate and directed to the GC-SOAs for amplification.

The phase shifters 114 may include any component suitable for modifying a phase of the seed light 104 provided to any of the SOAs 106 such that the SOA output beams 108 may be phase-locked. For example, a phase shifter 114 may include, but is not limited to, a Si waveguide phase modulator (e.g., utilizing thermo-optic or carrier injection).

In some embodiments, the light source 100 includes a controller 116 with one or more processors 118 configured to execute a set of program instructions maintained in a memory 120, or memory device, where the program instructions may cause the processors 118 to implement various actions. The controller 116 may further be communicatively coupled with any other components of the light source 100 including, but not limited to, the control sub-system 122 (or a component therein such as a detector 124) or the phase shifters 114.

The one or more processors 118 of a controller 116 may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors 118 may include any device configured to execute algorithms and/or instructions (e.g., program instructions stored in memory). In some embodiments, the one or more processors 118 may be embodied as a desktop computer, mainframe computer system, workstation, image computer, parallel processor, networked computer, or any other computer system configured to execute a program configured to operate or operate in conjunction with the light source 100. Therefore, the above description should not be interpreted as a limitation on the embodiments of the present disclosure but merely as an illustration. Further, the steps described throughout the present disclosure may be carried out by a single controller or, alternatively, multiple controllers. Additionally, the controller 116 may include one or more controllers housed in a common housing or within multiple housings. In this way, any controller or combination of controllers may be separately packaged as a module.

The memory 120 may include any storage medium known in the art suitable for storing program instructions executable by the associated one or more processors 118. For example, the memory 120 may include a non-transitory memory medium. By way of another example, the memory 120 may include, but is not limited to, a read-only memory (ROM), a random-access memory (RAM), a magnetic or optical memory device (e.g., disk), a magnetic tape, a solid-state drive and the like. It is further noted that the memory 120 may be housed in a common controller housing with the one or more processors 118. In some embodiments, the memory 120 may be located remotely with respect to the physical location of the one or more processors 118 and the controller 116. For instance, the one or more processors 118 of the controller 116 may access a remote memory (e.g., server), accessible through a network (e.g., internet, intranet and the like).

In some embodiments, the light source 100 includes a control sub-system 122 including one or more detectors 124 to characterize and control phases and/or amplitudes of the GC-SOAs 106 (or the associated SOA output beams 108). For example, the control sub-system 122 may provide that the SOA output beams 108 from the GC-SOAs 106 are phase locked to each other. The control sub-system 122 may include any optical elements and any number or type of detectors 124 suitable for characterizing the phases and/or amplitudes of the GC-SOAs 106. As a non-limiting example, the control sub-system 122 may be provided as an off-axis digital holography (DH) system in which seed light 104 (e.g., a picked-off portion of seed light 104 from the seed source 102 is interfered with the SOA output beams 108 and/or tapped light from the GC-SOAs 106 on a detector 124. In this way, the detector 124 may provide detection signals indicative of at least the phases of the SOA output beams 108 suitable for control of the phase shifters 114 to enable phase locking of SOA output beams 108.

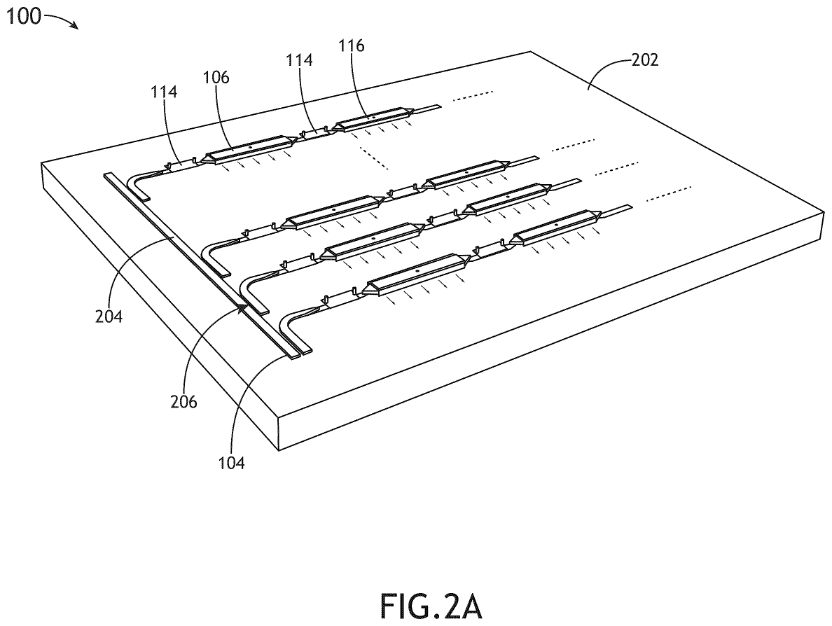

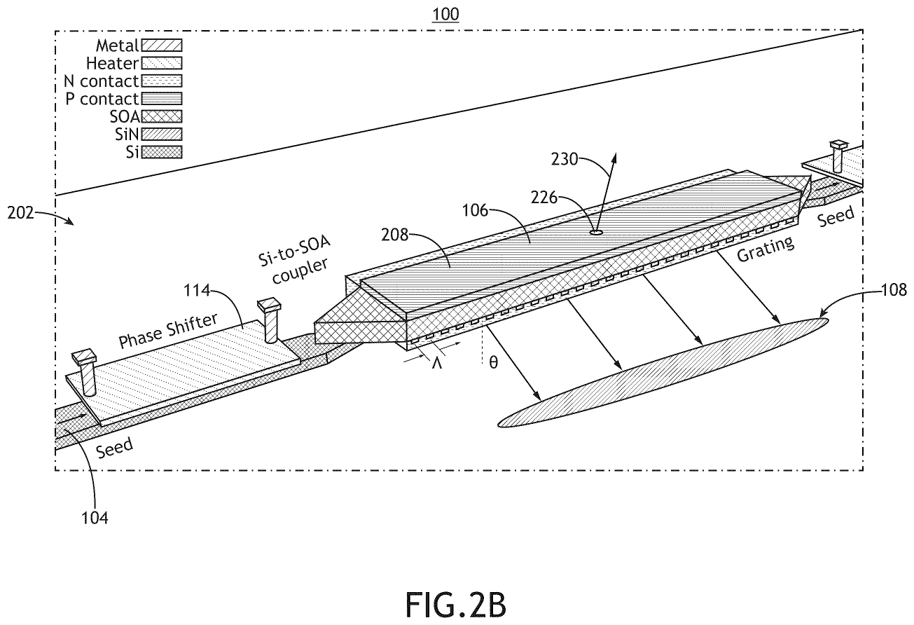

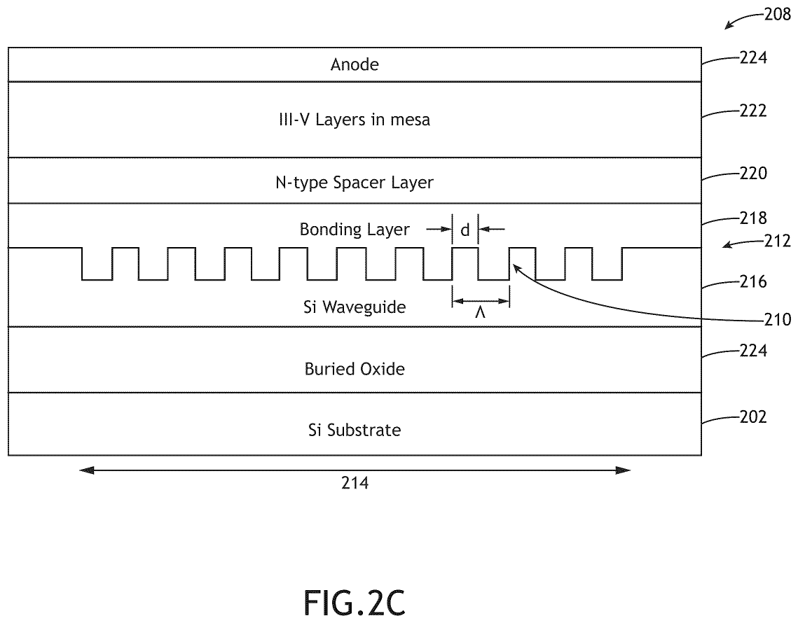

FIGS. 2A-2C includes illustrations of one non-limiting configuration of the light source 100, in accordance with one or more embodiments of the present disclosure. FIG. 2A is a perspective view of an array of GC-SOAs 106 on a common substrate 202, in accordance with one or more embodiments of the present disclosure. FIG. 2B is a magnified view of a portion of the light source 100 in FIG. 2A depicting an SOA 106 and a phase shifter 114, in accordance with one or more embodiments of the present disclosure. FIG. 2C is a cross-section schematic of a GC-SOA 106, in accordance with one or more embodiments of the present disclosure.

In some embodiments, the light source 100 includes one or more waveguides 204 to distribute the seed light 104 to the GC-SOAs 106 for amplification. Further, the light source 100 may include any number of phase shifters 114 at any locations to adjust the phase of the seed light 104 to provide that the output light from the various GC-SOAs 106 is phase locked. For example, FIGS. 2A and 2B depict phase shifters 114 prior to each GC-SOA 106.

A GC-SOA 106 may have any design suitable for amplifying seed light 104 and directing at least a portion of the amplified seed light 104 as a SOA output beam 108 at a non-zero angle from the direction of propagation of the seed light 104 and of a surface of the substrate 202 more generally. For example, FIG. 2C illustrates a non-limiting configuration of a GC-SOA 106 including a grating 210 within a waveguiding region 212 suitable for guiding the seed light 104, where the grating 210 has periodicity along a longitudinal direction 214 (e.g., a direction of propagation of the seed light 104). In particular, the waveguiding region 212 of the GC-SOA 106 in FIG. 2C is formed as a structured silicon layer 216 covered by a bonding layer 218. Further, this waveguiding region 212 may be fabricated on an oxide layer 224 over the substrate 202 and further covered by additional layers such as, but not limited to, a spacer layer 220 (e.g., an N-type spacer layer 220) and one or more III-V layers 222. Finally, FIG. 2C depicts an anode 224, which may be used for pumping the GC-SOA 106.

Additionally, a GC-SOA 106 may include, but is not required to include, a tapered coupler 226 on an input or output end of the waveguiding region 212 to facilitate coupling of light with the waveguides 204.

In a GC-SOA 106, the seed light 104 is amplified along a longitudinal direction 214 (e.g., a direction of propagation of the seed light 104), but coupled out of the substrate 202 using a grating at a different angle (θ), which results in an elliptical SOA output beam 108 extended along the longitudinal direction 214 (e.g., by an amount associated with a length of the grating 210 of the GC-SOA 106 along the longitudinal direction 214. The outcoupling of an SOA output beam 108 at a direction θ may be described by Equation (1):

$${β}_{SOA} - \frac{2 π}{Λ} = \frac{2 π}{λ} sin θ$$

where A is a period of a grating in the GC-SOA 106, 1 is a wavelength of the seed light 104, and β_{soA} relates to the propagation parameters. Further, various parameters of the grating 210 (e.g., depth, duty cycle, or the like) may be selected to provide a desired output beam profile of the SOA output beam 108 (e.g., Gaussian, flat-top, or the like).

The GC-SOAs 106 may be distributed in any arrangement. In some embodiments, the GC-SOAs 106 are arranged into an array having any two-dimensional pattern on the substrate 202. In this way, the SOA output beams 108 may have any corresponding two-dimensional pattern.

In some embodiments, the two or more rows, where seed light 104 is coupled to each row. As an illustration, the GC-SOAs 106 are arranged into an array having two or more rows, where each row includes at least one GC-SOA 106. It is contemplated herein that each GC-SOA 106 may not have 100% efficiency such that a portion of the seed light 104 may not be outcoupled as an SOA output beam 108. As a result, this portion of the seed light 104 may continue propagating through the GC-SOA 106.

It is further contemplated herein that providing multiple GC-SOAs 106 along a row may allow for efficient amplification of the seed light 104. In particular, portions of seed light 104 not outcoupled by one GC-SOA 106 in a row may be provided as an input to a subsequent GC-SOA 106 in the row. As an illustration, FIG. 2A depicts a configuration where a high-power seed source 102 may distribute the seed light 104 in a waveguide 204 (e.g., a SiN waveguide) through a series of couplers 206 to split the seed light 104 into the various rows (e.g., one coupler 206) for each of M rows of SOAs 106). In this configuration, each GC-SOA 106 in a second column is seeded by the GC-SOA 106 in a first column (e.g., by light propagating through the GC-SOA 106 that is not outcoupled by the grating in the GC-SOA 106). The process is repeated from one column to the next, thereby an amplifier is seeded by the amplifier in the previous column until the last column N.

Further, A P contact 208 (e.g., including an anode 224) on the top of the GC-SOA 106 may also serve as a mirror for preferential output coupling through the substrate 202 only. Residual light remaining in the GC-SOA 106 may propagate to a subsequent GC-SOA 106 in the row (e.g., as seed light 104).

In some embodiments, the GC-SOAs 106 include one or more openings 228 in the P contact 208 (or any other portion of the GC-SOA 106) to allow a portion of amplified light to exit the GC-SOAs 106 from an opposite side as the SOA output beams 108 (e.g., as tapped light). Such a configuration may be suitable for diagnostic purposes (e.g., by the control sub-system 122). For example, FIG. 2B depicts an opening 228 in each GC-SOA 106 to provide tapped light 230 (e.g., a portion of amplified seed light 104) from an opposing side of the substrate 202.

It is noted that the incorporation of an array of GC-SOAs 106 in the light source 100 may have numerous advantages. First, the peak intensity inside a GC-SOA 106 may be orders of magnitude lower than for an edge-emitting SOA. This is because the total power created by the GC-SOA 106 is contained in an area W·L, whereas the same power is contained in an area W·t for a conventional edge-emitting SOA, where W, L, t are the width, length, and thickness of the SOA active region. Since the length of the SOA is on the order of millimeters and the thickness of the SOA is on the order of microns, the peak intensity of a CG-SOA 106 is three orders of magnitude lowers than that of the conventional SOA. Second, the coherently combined output beam 112 from the light source 100 inherits its temporal characteristics from the seed from CW to the nano-second time scale. This flexibility would be very difficult to achieve for coherently combining of lasers, yet it is extremely useful for different kinds of direct energy and materials processing applications.

It should be understood, however, that the particular depiction of a GC-SOA 106 in FIGS. 2A-2C is provided merely for illustrative purposes and should not be interpreted as limiting the scope of the present disclosure. For example, a GC-SOA 106 may have any design and be formed from any materials (or groups of materials) suitable for providing amplification of seed light 104 and generation of an SOA output beam 108 at a non-zero angle relative to a direction of propagation of the seed light 104. In this way, the materials and/or architectures may be adjusted based on the particular application and/or wavelength requirements.

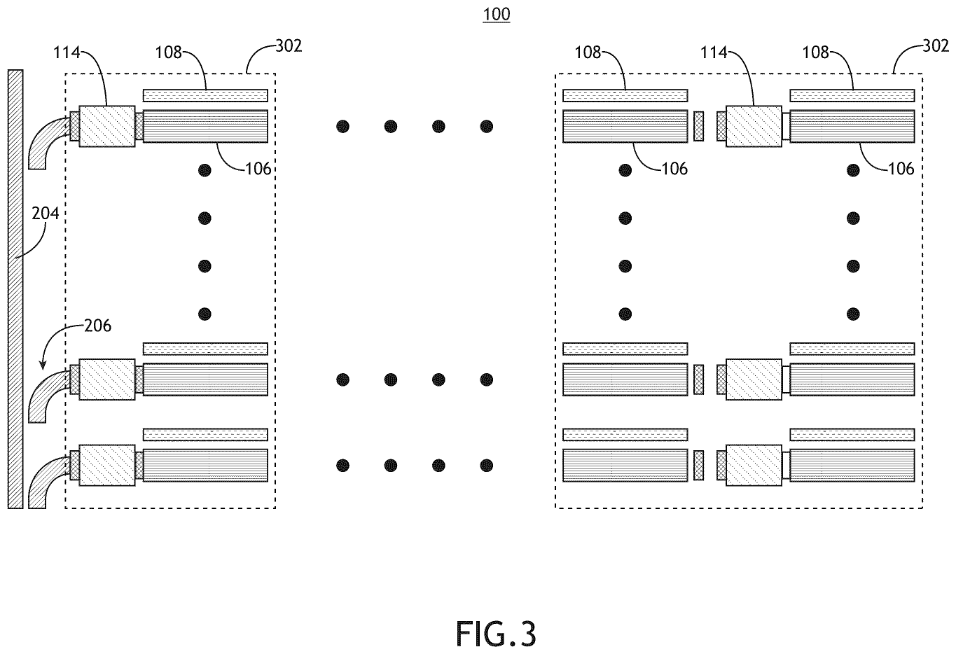

FIG. 3 is a conceptual top view of a GC-SOA 106 array, in accordance with one or more embodiments of the present disclosure. In some embodiments, the light source 100 may include a series of tiles 302 (e.g., or panels), each including an array of GC-SOAs 106 to further increase the power on demand. For example, in the case that a single tile 302 provides power on the order of kW, a light source 100 including multiple tiles 302 may provide scaled power on the order of 100s of kWs or greater.

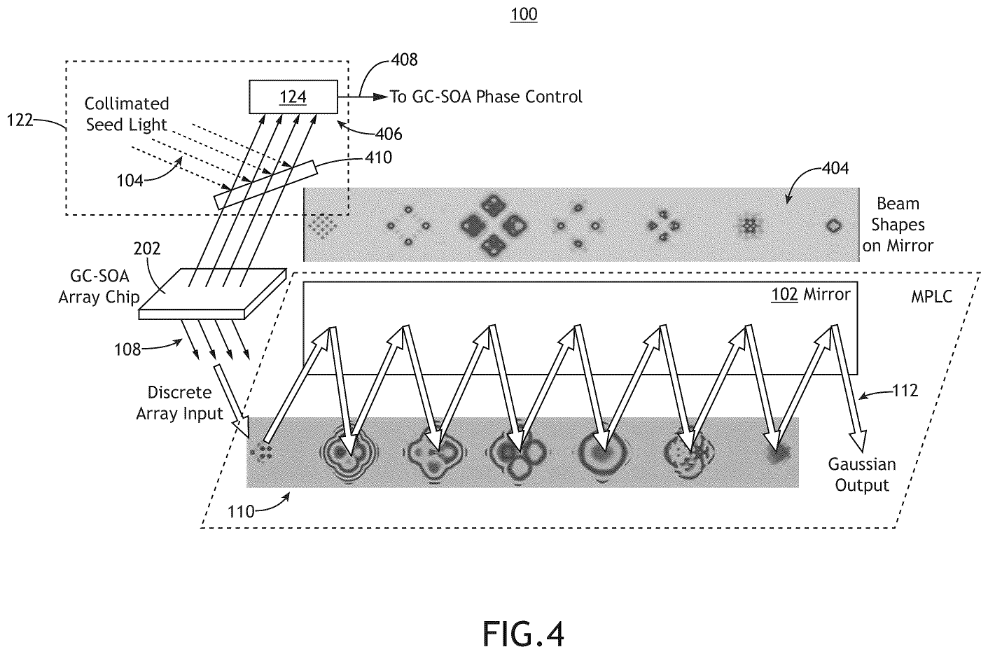

Referring now to FIG. 4, the use of a series of phase masks 110 to coherently combine the SOA output beams 108 into a single output beam 112 is described in greater detail, in accordance with one or more embodiments of the present disclosure. In some embodiments, the phase masks 110 operate as an MPLC device.

In a general sense, the phase masks 110 may operate in any combination of transmissive or reflective modes. FIG. 4 is a schematic illustration of a non-limiting example of a light source 100 with reflective phase masks 110 for coherent beam combining, in accordance with one or more embodiments of the present disclosure. In FIG. 4, seven reflective phase masks are used to combine the SOA output beam 108 to a single Gaussian output beam 112. For example, light associated with the SOA output beams 108 is successively reflected between the phase masks 110 and a mirror 402 to provide the final output beam 112. The inset 404 depicts the progression of the intensity of light associated with the SOA output beams 108 as they are combined to form the output beam 112.

FIG. 4 also depicts control of the phases and/or amplitudes of the GC-SOAs 106. For example, FIG. 4 depicts a control sub-system 122 formed as an off-axis DH system for the measurement of the phases of tapped light 230 from the GC-SOAs 106. In FIG. 4, the control sub-system 122 includes an interferometer 406 to interfere light from openings 228 in the GC-SOAs 106 (e.g., as depicted in FIG. 2B) with seed light 104 (e.g., a portion of the seed light 104 provided by the seed source 102) onto a detector 124 formed as a multi-pixel camera. In this configuration, the detector 124 may provide detection signals 408 indicative of at least one of phases or amplitudes of the SOA output beams 108 (which have a well-defined phase relationship with the tapped light 230). For example, the controller 116 may receive the detection signals 408 and generate control signals (not shown) for the phase shifters 114 based on the detection signals 408 (e.g., using feedback control techniques) to ensure that the SOA output beams 108 are phase locked with respect to each other.

The interferometer 406 may include any components or combination of components suitable for interfering light. For example, as depicted in FIG. 4, the interferometer 406 may include a beam combiner 410 to combine the seed light 104 and the light from the GC-SOAs 106 (e.g., the tapped light 230).

In this way, FIG. 4 shows how the SOA output beams 108 are used 1) to form a coherent Gaussian beam from the substrate side (bottom) using the phase masks 110 and 2) to sense the phases and amplitudes of the light in all the SOAs 106 in a scalable fashion using light radiated into the cladding (top) to realize phase and amplitude control of each GC-SOA 106, resulting in the desired Gaussian beam at the output.

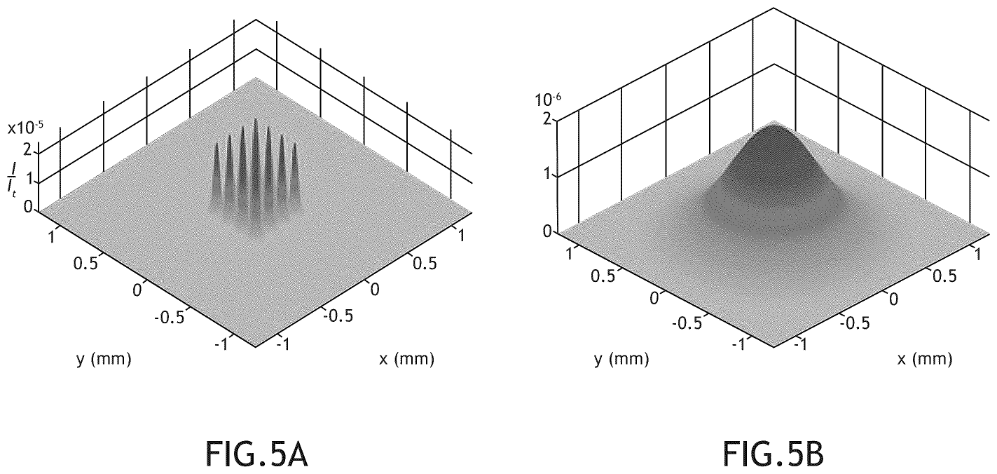

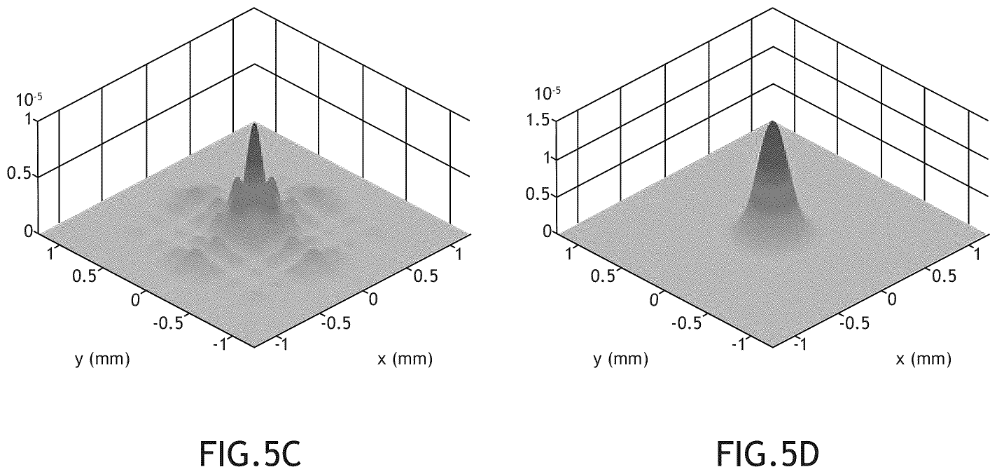

The operation of the phase masks 110 as an MPLC is now described in greater detail, in accordance with one or more embodiments of the present disclosure. FIG. 5A is a plot of intensity of an array of 16 Gaussian beams (e.g., associated with laser output in the fundamental Gaussian mode), in accordance with one or more embodiments of the present disclosure. FIG. 5B is a far-field intensity plot of the beams in FIG. 5A in the case that the beams are incoherent with respect to each other, in accordance with one or more embodiments of the present disclosure. In this case, the far-field distribution is described by a broad Gaussian peak. FIG. 5C is a far-field intensity plot of the beams in FIG. 5A in the case that the beams are coherent with respect to each other, in accordance with one or more embodiments of the present disclosure. In this case, the far-field distribution is characterized by a main peak at the center surrounded by rings of side lobes. FIG. 5D is a far-field intensity plot of the beams in FIG. 5B upon coherent combination with phase masks 110 operating as an MPLC, in accordance with one or more embodiments of the present disclosure. The far-field intensity plots in FIGS. 5B-5D, were taken at a distance of 25 cm.

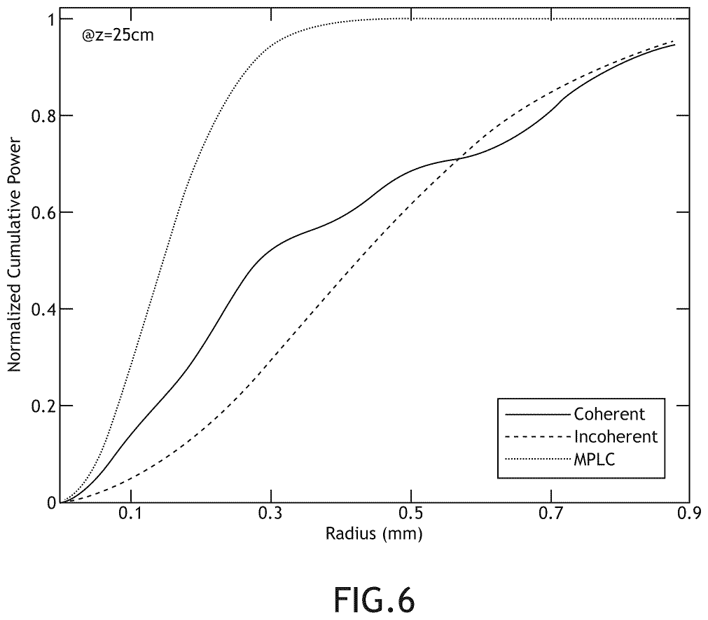

FIG. 6 is a plot of normalized cumulative power (e.g., power in the bucket) as a function of beam radius for the intensity plots of FIGS. 5B-5D, in accordance with one or more embodiments of the present disclosure.

Because the main peak at the center in FIG. 5C is much narrower than that from the incoherent case shown in FIG. 5B, one might deduce that the coherent laser array would be much more effective than the incoherent laser array. However, as shown in FIG. 6, the radii of the beams for power-in-the-bucket above 70% are nearly identical for the incoherent and coherent arrays (e.g., FIGS. 5B and 5C, respectively). The reason for this counterintuitive result is the existence of the side lobes. Each of them may contain a small amount of power but, in aggregate, they account for a significant portion of the total power in the laser array. Therefore, it is imperative to modify the spatial properties of coherent array to increase the power-in-the-bucket. Otherwise, phase locking of emitter arrays would have been in vain.

It is contemplated herein that the phase masks 110 provide the requisite shaping to increase this normalized cumulative power distribution. In particular, the phase masks 110 shape the discrete, coherent phase locked arrays into one single Gaussian, as shown in FIG. 5D. The resulting power-in-the-bucket is also significantly enhaced in comparison with phase locking alone, as shown in FIG. 5C.

MPLC is generally described in J.-F. Morizur et al., Programmable unitary spatial mode manipulation. J. Opt. Soc. Am. A 27, 2524-2531 (2010), which is incorporated herein by reference in its entirety. When a sufficient number of phase modulations and free-space propagations are cascaded, an arbitrary unitary transformation, which is the case between the input phased locked array and the output Gaussian beam, can be constructed. Referring again to FIG. 4, FIG. 4 illustrates calculated phase patterns for the seven phase masks 110 used for coherent beam combining of a 16-element array of SOA output beams 108 as well as the evolution of the beam profile from 16 discrete inputs to one fundamental Gaussian beam through the 7 phase masks 110. Each phase mask modulates the wavefront of the incident light and free-space propagation converts the phase modulation into intensity redistribution through diffraction.

The patterns of the phase masks 110 may be calculated using any suitable technique. The patterns used in the example of FIG. 4 a wavefront matching algorithm was used for iteratively updating the phase patterns. Wavefront matching algorithms are generally described in Y. Sakamaki, T. Saida, T. Hashimoto, H. Takahashi, New Optical Waveguide Design Based on Wavefront Matching Method. Journal of Lightwave Technology 25, 3511-3518 (2007), which is incorporated herein by reference in its entirety.

It is contemplated that MPLC-based beam combining as disclosed herein may be scalable for large numbers of SOA output beams 108 to provide a high-power output beam 112. For example, simulations have indicated that coherent combination of up to 256 beams only requires seven phase masks 110 in some cases. It is further noted that systems with phase masks 110 can achieve losses as low as 1 dB (or lower).

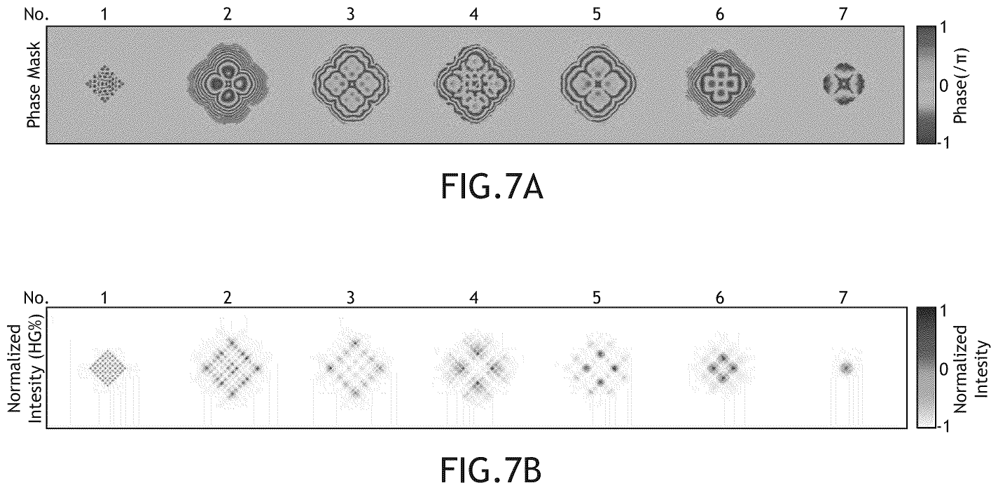

FIG. 7A is a plot of seven phase mask patterns suitable for combining an array of 64 SOA output beams 108, in accordance with one or more embodiments of the present disclosure. FIG. 7B is a plot of intensity distributions associated with the conversion of the 64 SOA output beams 108 to a single Gaussian output beam 112, in accordance with one or more embodiments of the present disclosure. As shown in FIGS. 7A and 7B, the phase masks 110 effectively combine the array of SOA output beams 108 to a high-density Gaussian output beam 112.

However, it is contemplated herein that phase masks 110 (and the MPLC technique more generally) may be used to provide an output beam 112 with any desired output profile. In this way, the illustrations of a Gaussian output beam 112 are merely illustrative and should not be interpreted as limiting the present disclosure.

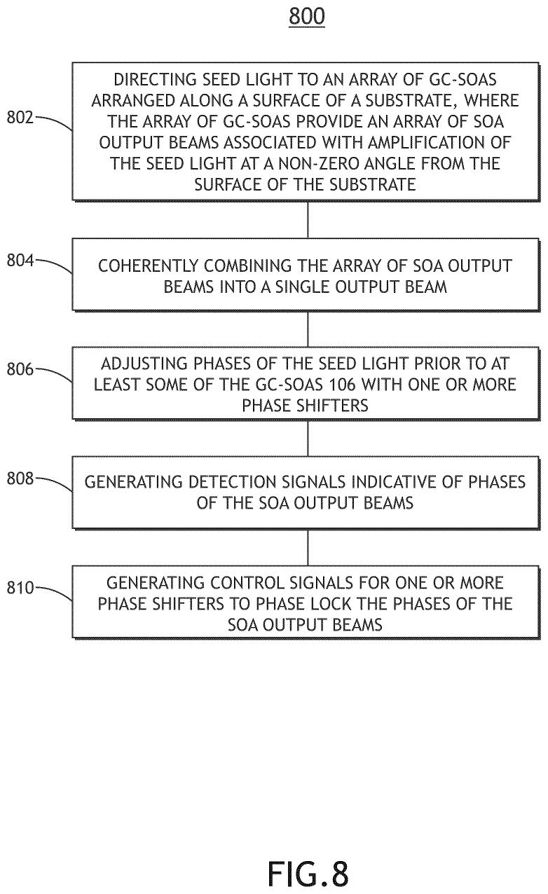

Referring now to FIG. 8, FIG. 8 is a flow diagram illustrating steps performed in a method 800 for amplifying light, in accordance with one or more embodiments of the present disclosure. The embodiments and enabling technologies described previously herein in the context of the light source 100 should be interpreted to extend to the method 800. For example, the one or more processors 118 of the controller 116 may be configured to execute program instructions stored on memory 120 causing the one or more processors 118 to perform any of the steps of the method 800 directly or indirectly. It is further noted, however, that the method 800 is not limited to the architecture of the light source 100.

In some embodiments, the method 800 includes a step 802 of directing seed light to an array of GC-SOAs arranged along a surface of a substrate 202, where the array of GC-SOAs provide an array of SOA output beams 108 associated with amplification of the seed light at a non-zero angle from the surface of the substrate 202.

In some embodiments, the method 800 includes a step 804 of coherently combining the array of SOA output beams 108 into a single output beam. For example, the step 804 may combine the SOA output beams 108 using a series of phase plates (e.g., configured as an MPLC device).

In some embodiments, the method 800 includes a step 806 of adjusting phases of the seed light 104 prior to at least some of the GC-SOAs 106 with one or more phase shifters 114.

In some embodiments, the method 800 includes a step 808 of generating detection signals indicative of phases of the SOA output beams 108. The detection signals may be generated using any technique known in the art such as, but not limited to, a DH technique.

In some embodiments, the method 800 includes a step 810 of generating control signals (e.g., via the controller 116) for one or more phase shifters 114 to phase lock the phases of the SOA output beams 108.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A light source comprising:
an array of grating-coupled semiconductor optical amplifiers (GC-SOAs) arranged along a surface of a substrate, wherein the array of GC-SOAs receive seed light from a common seed source, wherein the array of GC-SOAs provide an array of SOA output beams associated with amplification of the seed light at a non-zero angle from the surface of the substrate.

2. The light source of claim 1, further comprising:
one or more phase shifters configured to provide that the SOA output beams are phase-locked.

3. The light source of claim 1, further comprising:
a plurality of phase masks configured to coherently combine the array of SOA output beams into a single output beam.

4. The light source of claim 3, wherein the plurality of phase masks are associated with a multi-plane light conversion (MPLC) device.

5. The light source of claim 3, wherein the single output beam has a Gaussian profile.

6. The light source of claim 3, wherein the plurality of phase masks are reflective phase masks, wherein the light source further comprises a mirror, wherein light associated with the array of SOA output beams is successively reflected between the mirror and the plurality of phase masks to coherently combine the array of SOA output beams into the single output beam.

7. The light source of claim 3, wherein the plurality of phase masks are transmissive phase masks, wherein light associated with the array of SOA output beams is successively transmitted through the plurality of phase masks to coherently combine the array of SOA output beams into the single output beam.

8. The light source of claim 1, wherein the array of GC-SOAs is arranged as two or more rows of GC-SOAs, wherein the light source further comprises:
one or more couplers arranged to split the seed light into the two or more rows.

9. The light source of claim 8, wherein light not outcoupled as one of the SOA output beams from at least one GC-SOA in a particular row of the two or more rows seeds at least one subsequent GC-SOA in the array of GC-SOAs in the row.

10. A light source comprising:
an array of grating-coupled semiconductor optical amplifiers (GC-SOAs) arranged along a surface of a substrate, wherein the array of GC-SOAs receive seed light from a common seed source, wherein the array of GC-SOAs provide an array of SOA output beams associated with amplification of the seed light at a non-zero angle from the surface of the substrate;
one or more phase shifters configured to control phases of the SOA output beams;
a control sub-system including one or more detectors configured to generate detection signals indicative of phases of the SOA output beams; and
a controller communicatively coupled to the one or more phase shifters and the one or more detectors, wherein the controller includes one or more processors configured to execute program instructions stored on a memory device, wherein the program instructions are configured to cause the one or more processors to;
receive the detection signals from the one or more detectors; and
generate control signals for the one or more phase shifters based on the detection signals to phase lock the SOA output beams.

11. The light source of claim 10, wherein the control sub-system further comprises:
an interferometer configured to interfere a portion of the seed light with at least one of a portion of the SOA output beams or tapped light from the GC-SOAs onto one of the one or more detectors.

12. The light source of claim 11, wherein the one or more detectors comprise:
a multi-pixel detector.

13. The light source of claim 10, further comprising:
a plurality of phase masks configured to coherently combine the array of SOA output beams into a single output beam.

14. The light source of claim 13, wherein the plurality of phase masks are associated with a multi-plane light conversion (MPLC) device.

15. The light source of claim 13, wherein the single output beam has a Gaussian profile.

16. The light source of claim 13, wherein the plurality of phase masks are reflective phase masks, wherein the light source further comprises a mirror, wherein light associated with the array of output beams is successively reflected between the mirror and the plurality of phase masks to coherently combine the array of output beams into the single output beam.

17. The light source of claim 13, wherein the plurality of phase masks are transmissive phase masks, wherein light associated with the array of output beams is successively transmitted through the plurality of phase masks to coherently combine the array of output beams into the single output beam.

18. The light source of claim 10, wherein the array of GC-SOAs is arranged as two or more rows of GC-SOAs, wherein the light source further comprises:
one or more couplers arranged to split the seed light into the two or more rows.

19. The light source of claim 18, wherein light not outcoupled as one of the SOA output beams from at least one GC-SOA in a particular row of the two or more rows seeds at least one subsequent GC-SOA in the array of GC-SOAs in the row.

20. A method comprising:
directing seed light to an array of grating-coupled semiconductor optical amplifiers (GC-SOAs) arranged along a surface of a substrate, wherein the array of GC-SOAs provide an array of SOA output beams associated with amplification of the seed light at a non-zero angle from the surface of the substrate; and
coherently combining the array of SOA output beams into a single output beam.

21. The method of claim 20, wherein coherently combining the array of SOA output beams into a single output beam comprises:
coherently combining the array of SOA output beams into a single output beam with a plurality of phase masks.

22. The method of claim 21, wherein the plurality of phase masks are associated with a multi-plane light conversion (MPLC) device.

23. The method of claim 21, further comprising:
adjusting phases of the seed light prior to at least some of the GC-SOAs with one or more phase shifters.

24. The method of claim 21, further comprising:
generating detection signals indicative of phases of the SOA output beams; and
generating control signals for one or more phase shifters to phase lock the phases of the SOA output beams.
